(19) United States
(12) Patent Application Publication
(10) Pub. No.: US 2007/0090869 A1
(43) Pub. Date: Apr. 26, 2007

(54) Combined power source and printed transistor circuit apparatus and method

(75) Inventors: Hakeem B. Adewole, Schaumburg, IL (US); Paul W. Brazis, South Elgin, IL (US); Gabriela Dyrc, Hoffman Estates, IL (US); Daniel R. Gamota, Palatine, IL (US); Jie Zhang, Buffalo Grove, IL (US)

Correspondence Address: FITCH EVEN TABIN AND FLANNERY, 120 SOUTH LA SALLE STREET, SUITE 1600, CHICAGO, IL, 60603-3406, US

(73) Assignee: Motorola, Inc.

(21) Appl. No.: 11/259,481

(22) Filed: Oct. 26, 2005

(51) Int. Cl. H03K 17/56

(52) U.S. Cl. 327/425

(57) ABSTRACT

A power source (201) and a printed transistor circuit (202) are combined with one another in a stacked and integral configuration. In a preferred though optional configuration this combination can further comprise a substrate (200) of choice. The power source can comprise a technology of choice such as, but not limited, to, a battery or a photovoltaic element. These elements can be combined (104) using a joining technology of choice such as, but not limited to, laminating these elements together or printing one upon the other.

### TECHNICAL FIELD

This invention relates generally to semiconductor devices and more particularly to semiconductor devices that have at least one printed device element.

### BACKGROUND

Methods and apparatus that use such techniques as vacuum deposition to form semiconductor-based devices of various kinds are well known. Such techniques serve well for many purposes and can achieve high reliability, small size, and relative economy when applied in high volume settings. Recently, other techniques are being explored to yield semiconductor-based devices. For example, organic and inorganic semiconductor materials can be provided as a functional ink and used in conjunction with various printing techniques to yield printed semiconductor devices.

Printed semiconductor devices, however, yield considerably different end results and make use of considerably different fabrication techniques than those skilled in the art of semiconductor manufacture are prone to expect. For example, printed semiconductor devices tend to be considerably larger than typical semiconductor devices that are fabricated using more traditional techniques. As other examples, both the materials employed and the deposition techniques utilized are also well outside the norm of prior art expectations.

Printed circuitry appears to offer a potential competitive advantage when applied in particular application settings such as smart packaging or the like. Actual deployment of such technology, however, remains at least partially discouraged by other factors that can offset the otherwise low-cost and low-profile benefits of such an approach. For example, electrical circuits require a power source. While power sources can be relatively small (such as hearing aid-style batteries) their cost can be prohibitively high (at least for some applications). In other cases even the relatively small form factor of existing stand alone power cells can be unsuitable to some applications that might otherwise benefit from printed semiconductor circuits. Disposability and assembly issues can also discourage the use of such power sources for at least some applications.

### BRIEF DESCRIPTION OF THE DRAWINGS

The above needs are at least partially met through provision of the combined power source and printed transistor circuit apparatus and method described in the following detailed description, particularly when studied in conjunction with the drawings, wherein:

FIG. 1 comprises a flow diagram as configured in accordance with various embodiments of the invention;

FIG. 2 comprises a side elevational schematic view as configured in accordance with various embodiments of the invention;

FIG. 3 comprises a side elevational logical view as configured in accordance with various embodiments of the invention;

FIG. 4 comprises a side elevational schematic view as configured in accordance with various embodiments of the invention;

FIG. 5 comprises a side elevational schematic view as configured in accordance with various embodiments of the invention;

FIG. 6 comprises a side elevational schematic view as configured in accordance with various embodiments of the invention;

FIG. 7 comprises a side elevational schematic view as configured in accordance with various embodiments of the invention;

FIG. 8 comprises a side elevational schematic view as configured in accordance with various embodiments of the invention; and

FIG. 9 comprises a side elevational schematic view as configured in accordance with various embodiments of the invention.

Skilled artisans will appreciate that elements in the figures are illustrated for simplicity and clarity and have not necessarily been drawn to scale. For example, the dimensions and/or relative positioning of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

Generally speaking, pursuant to these various embodiments, a power source and a printed transistor circuit are combined with one another in a stacked and integral configuration. In a preferred though optional configuration this combination can further comprise a substrate of choice. The power source can comprise a technology of choice such as, but not limited to, a battery or a photovoltaic element. These elements can be combined using a joining technology of choice such as, but not limited to, laminating these elements together or printing one upon the other.

So configured, a resultant structure tends to be relatively flat and thin and will occupy relatively little vertical space while nevertheless ensuring, at least for many application settings, an adequate supply of electrical power for the corresponding electronic circuit. Such a structure can be manufactured using known technology and printing platforms and can be produced in a relatively cost effective manner. This combination of low cost and low profile in turn makes the use of printed semiconductor circuits more suitable for use in a wider range of application settings than might ordinarily be supposed.

These and other benefits will become more evident to those skilled in the art upon making a thorough review and study of the following detailed description.

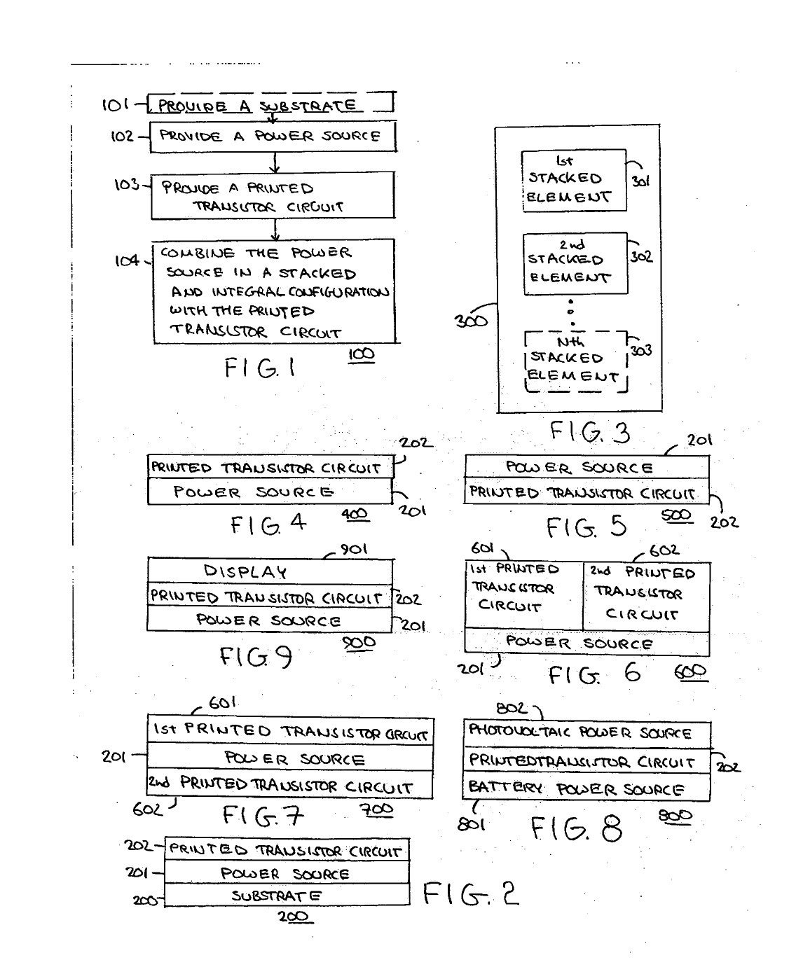

Referring now to the drawings, and in particular to FIG. 1, an overall process 100 representative of these various teachings comprises optionally but preferably providing 101 a substrate. This substrate can comprise any suitable material including various rigid and non-rigid materials. In a preferred embodiment, the substrate comprises a flexible substrate comprised, for example, of a plastic material such as polyester or a paper-like material. The substrate can be comprised of a single substantially amorphous material or can comprise, for example, a composite of differentiated materials (for example, a laminate construct). In a typical embodiment the substrate will comprise an electrical insulator though for some applications, designs, or purposes it may be desirable to utilize a material (or materials) that tend towards greater electrical conductivity.

This process 100 also provides for provision 102 of a power source such as, but not limited to, a battery (comprised of one or more cells), a photovoltaic element (such as but not limited to a solar cell), and so forth. In a preferred embodiment this power source comprises a substantially planar power source. Various power sources are presently known having a corresponding form factor and others will no doubt be developed in the future. For example, laminated batteries comprised of a pasty material applied to a paper-like substrate have long been used in the film pack industry. As a further example, at present many companies offer zinc carbon chemistry batteries that are formed using appropriate screen printed functional inks with other printing methodologies also being either used or presently considered and explored. As the present teachings are not particularly sensitive to the specific power source technology employed, and further as such technologies comprise a relatively well-understood area of endeavor, for the sake of brevity and the preservation of narrative focus further elaboration regarding such technologies will not be provided here.

This process 100 also then provides for provision 103 of a printed transistor circuit. These circuit elements are preferably, though not necessarily, comprised of one or more inks including, for example, inks that comprise semiconductor material. Those skilled in the printing arts are familiar with both graphic inks and so-called functional inks (wherein “ink” is generally understood to comprise a suspension, solution, or dispersant that is presented as a liquid, paste, or powder (such as a toner powder). These functional inks are further comprised of metallic, organic, or inorganic materials having any of a variety of shapes (spherical, flakes, fibers, tubes) and sizes ranging, for example, from micron to nanometer. Functional inks find application, for example, in the manufacture of some membrane keypads. Though graphic inks can be employed as appropriate in combination with this process, these inks are more likely, in a preferred embodiment, to comprise a functional ink.

In a preferred approach, such inks are placed on a printing substrate by use of a corresponding printing technique. Those familiar with traditional semiconductor fabrication techniques such as vacuum deposition will know that the word “printing” is sometimes used loosely in those arts to refer to such techniques. As used herein, however, the word “printing” is used in a more mainstream and traditional sense and does not include such techniques as vacuum deposition that involve, for example, a state change of the transferred medium in order to effect the desired material placement. Accordingly, “printing” will be understood to include such techniques as screen printing, offset printing, gravure printing, xerographic printing, flexographicy printing, inkjetting, microdispensing, stamping, and the like. It will be understood that these teachings are compatible with the use of a plurality of such printing techniques during fabrication of a given element such as a semiconductor device. For example, it may be desirable to print a first device element (or portion of a device element) using a first ink and a first printing process and a second, different ink using a second, different print process for a different device element (or portion of the first device element).

For purposes of illustration and not by way of limitation, a transistor can be formed using such materials and processes as follows. A gate can be printed on a substrate of choice using a conductive ink of choice (such as but not limited to a functional ink containing copper or silver, such as DuPont's Ag 5028 combined with 2% 3610 thinner). Pursuant to one approach, air is blown over the printed surface after a delay of, for example, four seconds. An appropriate solvent can then be used to further form, define, or otherwise remove excess material from the substrate. Thermal curing at around 120 degrees Centigrade for 30 minutes can then be employed to assure that the printed gate will suitably adhere to the substrate.

A dielectric layer may then be printed over at least a substantial portion of the above-mentioned gate using, for example, an appropriate epoxy-based functional ink (such as, for example, DuPont's 5018A ultraviolet curable material). By one approach, the dielectric layer comprises a laminate of two or more layers. When so fabricated, each layer can be cured under an ultraviolet lamp before applying a next layer.

Additional electrodes are then again printed and cured using, for example, a copper or silver-based electrically conductive functional ink (such as, for example, DuPont's Ag 5028 with 2% 3610 thinner). These additional electrodes can comprise, for example, a source electrode and a drain electrode. A semiconductor material ink, such as but not limited to an organic semiconductor material ink such as various formulations of polythiophene or a polythiophene-derived material such as poly(3-hexylthiophene) or an inorganic semiconductor material ink made of SnO₂, SnO, ZnO, Ge, Si, GaAs, InAs, InP, SiC, CdSe, and various forms of carbon (including carbon nanotubes), is then printed to provide an area of semiconductor material that bridges a gap between the source electrode and the drain electrode.

These teachings then provide for the combination 104 of the aforementioned power source and printed transistor circuit in a stacked and integral configuration as illustrated, for example, in FIG. 2. As illustrated, and pursuant to but one of many compliant configurations, a corresponding apparatus can comprise a substrate 200 having a power source 201 of choice stacked thereon and a printed transistor circuit 202 of choice further stacked on the power source 201. This configuration can be achieved in any of a variety of ways. For example, by one approach, these apparatus elements are separately constructed and then laminated one to the other to form the stacked integral structure depicted. As another approach, these apparatus elements can be printed one on the other.

In a preferred but optional approach, the printed transistor circuit is electrically coupled to and powered, at least in part, by the power source. Such an intercoupling can be readily achieved by using, for example, electrically conductive vias and/or exposed conductive paths on each element that couple one to the other (or, perhaps more preferably, by use of a shared material as where a battery electrode also comprises, for example, a transistor gate).

Those skilled in the art will understand that the aforementioned example comprises a non-exhaustive illustrative example only. Viewed more generally, and referring now to FIG. 3, these teachings will be understood to relate to an apparatus 300 having at least a first stacked element 301 (such as a power source and/or a printed transistor circuit) and a second stacked element 302 (such as a printed transistor circuit and/or a power source) wherein these stacked elements 301 and 302 are stacked with respect to one another in an integral fashion. If desired, any number of additional stacked elements can be readily accommodated as well (as represented by the Nth stacked element 303 shown in FIG. 3).

These teachings are readily employed to facilitate provision of a wide variety of potentially useful and expedient structures. As a first example, and as shown in FIG. 4, a printed transistor circuit 202 can be stacked atop a power source 201 to yield a first integrated stacked apparatus 400. As a second example, and as shown in FIG. 5, this relative positioning can be reversed such that the power source 201 is stacked atop the printed transistor circuit 202 to thereby yield a corresponding integrated stacked apparatus 500. Such a configuration may be useful, for example, in a setting when the power source 201 comprises a photovoltaic element and where this configuration will more likely result in successfully exposing the power source 201 to a light source during deployment and intended use.

As described above, a printed transistor circuit can be stacked and combined with a power source in an integral manner. If desired, a plurality of printed transistor circuits can be stacked and integrally combined with a power source. As a first illustration of such a configuration, and referring now to FIG. 6, a first printed transistor circuit 601 and a second printed transistor circuit 602 can both be stacked on a same side of the power source 201 to yield a corresponding integral stacked apparatus 600. As a second illustration of such a configuration, and referring now to FIG. 7, the first printed transistor circuit 601 can be disposed on a first side of the power source 201 while the second printed transistor circuit 602 is disposed on the opposing side of the power source 201 to yield a corresponding integrated stacked apparatus 700. Those skilled in the art will understand and appreciate that multiple transistor circuits, when so provided, may or may not be functionally interconnected depending upon the needs of a given application setting and/or the design requirements of a given designer.

In a similar manner, if desired, multiple power sources can be stacked and integrally combined with one or more printed transistor circuits. Such multiple power sources, when provided, can be combined in parallel with one another or can be arranged in series with one another. It would also be possible, of course, to offer them as discrete unrelated power sources that are not coupled to one another. It would also be possible to provide a variety of differing power sources using these teachings. To illustrate, and referring now to FIG. 8, a printed transistor circuit 202 can be disposed between a stacked configuration comprising a battery power source 801 and a photovoltaic power source 802. Such an apparatus 800 would then be able to provide power to the printed transistor circuit 202 using either or both of these alternative power sources 801 and 802. Or, if desired, the photovoltaic power source 802 could serve to recharge the battery power source 801 presuming, for example, that the printed transistor circuit 202 included, at least in part, appropriate recharging circuitry.

As noted above, these teachings readily accommodate stacking and integrally combining such power sources and transistor circuits with other elements if desired. As but one example of many to illustrate this point, and referring now to FIG. 9, a corresponding apparatus 900 can comprise a power source 201 and a printed transistor circuit 202 that are integrally stacked in common with an additional stacked element comprising a display 901 of choice. So configured, for example, the printed transistor circuit 202 can comprise, at least in part, a display driver as is known in the art and the power source 201 can serve to power both the display driver and the display 901 itself.

These teachings are readily usable to provide a wide variety of relatively inexpensive, thin, self-powered printed electronic active circuits. Such circuits can, in turn, be employed in a wide variety of application settings where present solutions are commercially or technologically unviable for one reason or another.

Those skilled in the art will recognize that a wide variety of modifications, alterations, and combinations can be made with respect to the above described embodiments without departing from the spirit and scope of the invention, and that such modifications, alterations, and combinations are to be viewed as being within the ambit of the inventive concept. As but one example of this, those skilled in the art will understand that one or more layers of the power source and the printed transistor circuit may be comprised of a same material (for example, copper may serve both as a power source electrode and as a gate electrode of a printed transistor). In such a case, the aforementioned integration can comprise, at least in part, printing the copper material at the same time for both elements.

We claim:

1. A method comprising:
providing a power source;
providing a printed transistor circuit;
combining the power source in a stacked and integral configuration with the printed transistor circuit.

2. The method of claim 1 wherein the power source comprises at least one of:
a battery;
a photovoltaic element.

3. The method of claim 1 wherein combining the power source in a stacked and integral configuration with the printed transistor circuit comprises laminating the power source with the printed transistor circuit.

4. The method of claim 1 wherein combining the power source in a stacked and integral configuration with the printed transistor circuit comprises printing one onto the other.

5. The method of claim 1 wherein providing a printed transistor circuit comprises providing a plurality of printed transistor circuits and wherein combining the power source in a stacked and integral configuration with the printed transistor circuit comprises combining the power source in a stacked and integral configuration with the plurality of printed transistor circuits.

6. The method of claim 1 wherein providing a power source comprises providing a substantially planar power source.

7. An apparatus comprising:
a power source;
a printed transistor circuit disposed in a stacked and integral manner with the power source.

8. The apparatus of claim 7 wherein the power source comprises at least one of:
a battery;
a photovoltaic element.

9. The apparatus of claim 7 wherein the power source and the printed transistor circuit are laminated one to the other.

10. The apparatus of claim 7 wherein one of the power source and the printed transistor circuit is printed on the other.

11. The apparatus of claim 7 wherein the printed transistor circuit is powered, at least in part, by the power source.

12. The apparatus of claim 7 further comprising at least one additional printed transistor circuit which also is disposed in a stacked and integral manner with the power source.

13. The apparatus of claim 12 wherein the printed transistor circuit and the at least one additional printed transistor circuit are disposed on opposing sides of the power source.

14. The apparatus of claim 12 wherein the printed transistor circuit and the at least one additional printed transistor circuit are disposed on a same side of the power source.

15. A method of providing a printed electric circuit having an integral power source, comprising:
providing a substrate;
forming a power source on the substrate;
printing a transistor circuit on the power source.

16. The method of claim 15 wherein the power source comprises a battery.

17. The method of claim 15 wherein the substrate comprises a flexible substrate.

18. The method of claim 17 wherein the flexible substrate comprises at least one of:
a paper-like substrate;
a plastic substrate.

19. The method of claim 15 wherein printing the transistor circuit on the power source comprises using at least one of:
a contact printing process;
a non-contact printing process.
